(19) United States
(12) Patent Application Publication
(10) Pub. No.: US 2017/0346027 A1
(43) Pub. Date: Nov. 30, 2017

(54) ELECTRONIC DEVICE, DISPLAY UNIT, AND ELECTRONIC APPARATUS

(71) Applicant: JOLED INC., Tokyo (JP)

(72) Inventors: Yuichiro ISHIYAMA, Tokyo (JP); Tomoatsu KINOSHITA, Tokyo (JP)

(21) Appl. No.: 15/590,160

(22) Filed: May 9, 2017

(30) Foreign Application Priority Data
May 31, 2016 (JP) 2016-108325

(51) Int. Cl. H01L 51/05; H01L 21/02; H01L 27/32; H01L 51/52

(52) U.S. Cl. CPC H01L 51/0533; H01L 51/5253; H01L 21/02425; H01L 21/02488; H01L 27/3248

(57) ABSTRACT

An electronic device includes a substrate, a barrier film, and one of an electrically-conductive layer and a semiconductor layer. The barrier film is provided on the substrate. The barrier film contains an inorganic polymer compound and an organic matter. One of the electrically-conductive layer and the semiconductor layer is provided on the substrate with the barrier film in between.

### CROSS REFERENCE TO RELATED APPLICATIONS

This application claims the benefit of Japanese Priority Patent Application JP 2016-108325 filed on May 31, 2016, the entire contents of which are incorporated herein by reference.

### BACKGROUND

The technology relates to an electronic device including one of an electrically-conductive layer and a semiconductor layer on a substrate, and to a display unit and an electronic apparatus that use the electronic device.

In recent years, an electronic device including, for example, a thin film transistor (TFT) is used in electronic apparatuses in various field. For example, reference is made to Japanese Unexamined Patent Application Publication No. 2002-222691. Such an electronic device includes a substrate, and layers such as a semiconductor layer are provided on the substrate.

### SUMMARY

The above-described electronic device including, for example, the thin film transistor may desirably maintain its characteristics stably.

It is desirable to provide an electronic device that makes it possible to stably maintain its characteristics, and to provide a display unit and an electronic apparatus that use the electronic device.

An electronic device according to an embodiment of the technology includes a substrate, a barrier film, and one of an electrically-conductive layer and a semiconductor layer. The barrier film is provided on the substrate. The barrier film contains an inorganic polymer compound and an organic matter. One of the electrically-conductive layer and the semiconductor layer is provided on the substrate with the barrier film in between.

A display unit according to an embodiment of the technology includes a substrate, a barrier film, one of an electrically-conductive layer and a semiconductor layer, and a display device layer. The barrier film is provided on the substrate. The barrier film contains an inorganic polymer compound and an organic matter. One of the electrically-conductive layer and the semiconductor layer is provided on the substrate with the barrier film in between. The display device layer is provided on one of the electrically-conductive layer and the semiconductor layer. The display device layer includes a plurality of pixels.

An electronic apparatus according to an embodiment of the technology is provided with a display unit. The display unit includes a substrate, a barrier film, one of an electrically-conductive layer and a semiconductor layer, and a display device layer. The barrier film is provided on the substrate. The barrier film contains an inorganic polymer compound and an organic matter. One of the electrically-conductive layer and the semiconductor layer is provided on the substrate with the barrier film in between. The display device layer is provided on one of the electrically-conductive layer and the semiconductor layer. The display device layer includes a plurality of pixels.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a schematic cross-sectional view of an outline configuration of a display unit according to an embodiment of the technology.

FIG. 2 schematically illustrates a configuration of a barrier film illustrated in FIG. 1.

FIG. 3 is an enlarged view of a portion A illustrated in FIG. 2.

FIG. 4 is an explanatory schematic cross-sectional view of a specific configuration of a TFT layer illustrated in FIG. 1.

FIG. 5 is an explanatory schematic plan view of a wiring line configuration of the display unit illustrated in FIG. 1.

FIG. 6 is a plan view of a configuration of a portion corresponding to a region P illustrated in FIG. 5.

FIG. 7A is a schematic cross-sectional view of a step of a method of manufacturing the display unit illustrated in FIG. 1.

FIG. 7B is a schematic cross-sectional view of a step following the step of FIG. 7A.

FIG. 7C is a schematic cross-sectional view of a step following the step of FIG. 7B.

FIG. 7D is a schematic cross-sectional view of a step following the step of FIG. 7C.

FIG. 8 is a schematic cross-sectional view of an outline configuration of a display unit according to Modification Example 1.

FIG. 9 is a schematic cross-sectional view of an outline configuration of a display unit according to Modification Example 2.

FIG. 10 is a schematic cross-sectional view of another example (1) of the display unit illustrated in FIG. 9.

FIG. 11 is a schematic cross-sectional view of another example (2) of the display unit illustrated in FIG. 9.

FIG. 12 is a schematic cross-sectional view of another example (3) of the display unit illustrated in FIG. 9.

FIG. 13 is a schematic cross-sectional view of an outline configuration of a display unit according to Modification Example 3.

FIG. 14 is a schematic cross-sectional view of another example (1) of the display unit illustrated in FIG. 13.

FIG. 15 is a schematic cross-sectional view of still another example (2) of the display unit illustrated in FIG. 13.

FIG. 16 is a schematic cross-sectional view of still another example (3) of the display unit illustrated in FIG. 13.

FIG. 17 is a schematic cross-sectional view of still another example (4) of the display unit illustrated in FIG. 13.

FIG. 18 is a schematic cross-sectional view of an outline configuration of a display unit according to Modification Example 4.

FIG. 19 is a schematic cross-sectional view of an outline configuration of a display unit according to Modification Example 5.

FIG. 20 is a block diagram illustrating a functional configuration of the display unit.

FIG. 21 is a block diagram illustrating a configuration of an imaging unit.

FIG. 22 is a block diagram illustrating a configuration of an electronic apparatus.

### DETAILED DESCRIPTION

Some embodiments of the technology are described in detail below, in the following order, with reference to the accompanying drawings.

1. Embodiment (an example of a display unit that includes a barrier film on a substrate)
2. Modification Example 1 (an example of a display unit that includes an insulating film between a substrate and a barrier film)
3. Modification Example 2 (an example of a display unit that includes an electric field shielding film between a substrate and a barrier film)
4. Modification Example 3 (an example of a display unit that includes an insulating film between a barrier film and a TFT layer)
5. Modification Example 4 (an example of a display unit that includes a metal thin film on a rear surface of a substrate)
6. Modification Example 5 (an example of a display unit that includes a wiring line layer)
7. Functional configuration example of a display unit
8. Example of an imaging unit
9. Example of an electronic apparatus

### Embodiment

### [Configuration]

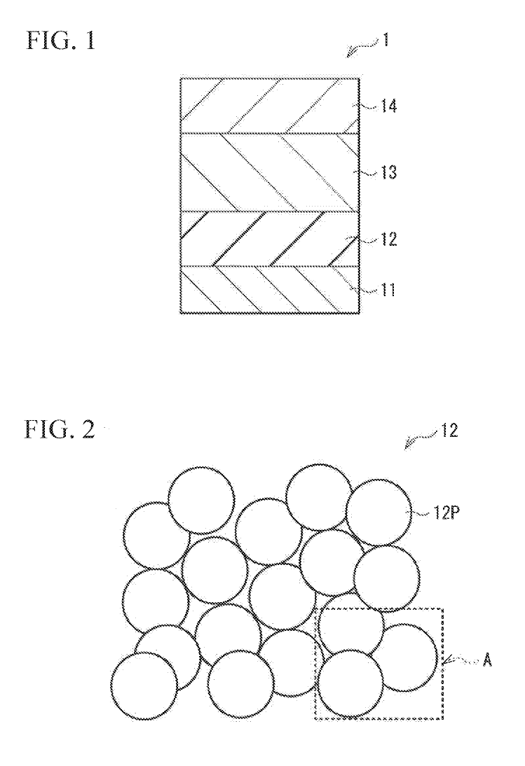

FIG. 1 schematically illustrates a cross-sectional configuration of a display unit (a display unit 1) according to an embodiment of the technology. The display unit 1 may be, for example, an organic electro-luminescence (EL) unit, and may include, for example, a barrier film 12, a TFT layer 13, and a display device layer 14 in this order on a substrate 11. Note that the configuration including the substrate 11, the barrier film 12, and the TFT layer 13 corresponds to a specific but non-limiting example of an “electronic device” in one embodiment of the technology.

The substrate 11 may be, for example, a flexible substrate (a substrate having flexibility). Examples of a material for forming the substrate 11 may include a resin material such as polyethylene terephthalate (PET), polyimide (PI), polycarbonate (PC), and polyethylene naphthalate (PEN). The examples of the material of the substrate 11 may further include polyamide and polyether sulfone (PES). In addition, the material is not limited to the resin material, and a metal film such as a stainless steel (SUS) film on which a film of an insulating material is formed may be used. Alternatively, the substrate 11 may also be made of, for example, a rigid material such as glass. The substrate 11 may have a thickness of, for example, 10 μm to 700 μm.

The barrier film 12 may be in contact with the substrate 11, and may be provided on an entire surface of the substrate 11. The barrier film 12 may prevent a substance that may become a contamination source, from moving from the substrate 11 to the TFT layer 13 and the display device layer 14. The substance that may become a contamination source may be a substance that deteriorates characteristics of the TFT layer 13 or the display device layer 14, and examples of such a substance may include moisture and sodium (Na). In the present embodiment, the barrier film 12 may contain an organic matter in addition to an inorganic polymer compound. This increases viscosity of a raw material when forming the barrier film 12, which makes it possible to easily increase the thickness of the barrier film 12. Therefore, the barrier film 12 has a function to planarize the substrate 11 in addition to the barrier function. This stably maintains characteristics of the display unit 1. The detail thereof is described later. The barrier film 12 may have a thickness of, for example, 0.1 μm to 10 μm, and preferably 4 μm or larger.

FIG. 2 schematically illustrates a configuration of the barrier film 12. The inorganic polymer compound contained in the barrier film 12 may be, for example, a silica compound that contains particles 12P each formed of silica nanoparticles. Each of the particles 12P may have a diameter of, for example, 10 nm to 1 μm. The inorganic polymer compound may be formed of only an inorganic element such as silicon (Si), oxygen (O), and hydrogen (H), without containing carbon (C). The inorganic polymer compound contained in the barrier film 12 may be, for example, diamond.

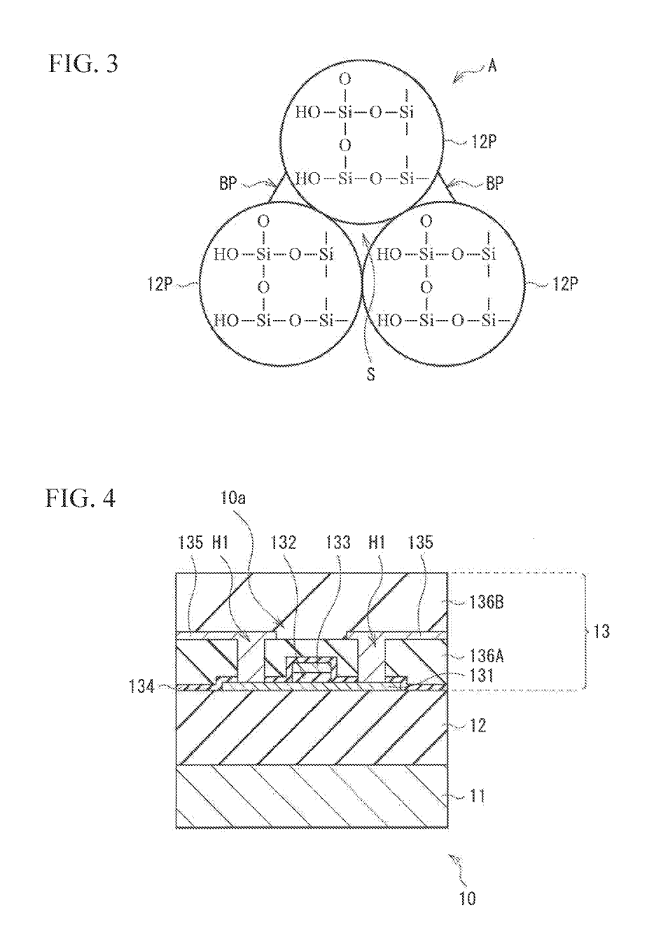

FIG. 3 illustrates a portion A illustrated in FIG. 2 in an enlarged manner. The organic matter contained in the barrier film 12 may be, for example, a siloxane organic material. More specifically, the organic matter may contain a siloxane bond (—Si—O—Si—) and an organic substituent, and examples thereof may include dimethylpolysiloxane. For example, an interparticle region BP between adjacent particles 12P may be crosslinked by the siloxane organic material (FIG. 3). When the interparticle region BP is crosslinked, the positions of the respective particles 12P are fixed, which improves stability of the barrier film 12 and improves durability to manufacturing process, etc. An organic matter such as the siloxane organic material may exist in a space S surrounded by the particles 12P. Alternatively, nothing may exist in the space S and the space S may be a gap. The organic matter contained in the barrier film 12 may be, for example, polyimide.

A volume ratio of the inorganic polymer compound to the organic matter which are contained in the barrier film 12 may be, for example, 10:1 to 10:5, and the organic matter contained in the barrier film 12 may be preferably 25% or lower in volume ratio. When the amount of the organic matter contained in the barrier film 12 is excessively large, the above-described barrier function of the barrier film 12 may be deteriorated.

FIG. 4 illustrates a specific configuration of the TFT layer 13 provided on the barrier film 12. The TFT layer 13 may be a layer including, for example, a thin film transistor (TFT 10a). For example, the TFT 10a may be a top-gate thin film transistor, and may include a semiconductor layer 131 in a selective region on the barrier film 12. A gate electrode 133 may be provided on the semiconductor layer 131 with a gate insulating film 132 in between. A protective film 134 and an interlayer insulating film 136A may be so provided as to cover the semiconductor layer 131, the gate insulating film 132, and the gate electrode 133. A contact hole H1 that faces a portion of the semiconductor layer 131 may be provided in the protection film 134 and in the interlayer insulating film 136A. A source-drain electrode 135 may be so provided on the interlayer insulating film 136A as to bury the contact hole H1, and an interlayer insulating film 136B may be so provided as to cover the interlayer insulating film 136A and the source-drain electrode 135.

The semiconductor layer 131 may be provided on the barrier film 12 through patterning. The semiconductor layer 131 may include a channel region (an active layer) in a region facing the gate electrode 133. The semiconductor layer 131 may be configured by an oxide semiconductor that contains, as a main component, an oxide of one or more of elements such as indium (In), gallium (Ga), zinc (Zn), tin (Sn), titanium (Ti), and niobium (Nb). More specifically, examples of the oxide may include indium tin zinc oxide (ITZO), indium gallium zinc oxide (IGZO or InGaZnO), zinc oxide (ZnO), indium zinc oxide (IZO), indium gallium oxide (IGO), indium tin oxide (ITO), and indium oxide (InO). Alternatively, the semiconductor layer 131 may be made of, for example, low-temperature polycrystalline silicon (LTPS) or amorphous silicon (a-Si).

The gate insulating film 132 may be configured by a monolayer film made of one of, for example, silicon oxide (SiOₓ), silicon nitride (SiNₓ), silicon oxynitride (SiON), and aluminum oxide (AlOₓ), or a layered film made of two or more thereof.

The gate electrode 133 may control carrier density in the semiconductor layer 131 with an applied gate voltage (Vg), and may serve as a wiring line that supplies potential. Examples of the material for forming the gate electrode 133 may include a simple substance containing one of titanium (Ti), tungsten (W), tantalum (Ta), aluminum (Al), molybdenum (Mo), silver (Ag), neodymium (Nd), and copper (Cu), and an alloy thereof. Alternatively, the material for forming the gate electrode 133 may be a compound containing one or more thereof, or a layered film containing two or more thereof. In addition, a transparent electrically-conductive film made of, for example, ITO may be used for the gate electrode 133.

The protection film 134 may be made of, for example, titanium oxide, aluminum oxide, indium oxide, or tin oxide, and may serve as a steam barrier film.

Each of the interlayer insulating films 136A and 136B may be made of an organic material such as an acrylic resin, polyimide (PI), and a novolac resin. Alternatively, a film made of an inorganic material, such as a silicon oxide film, a silicon nitride film, a silicon oxynitride film, and an aluminum oxide film may be used for the interlayer insulating film 136A.

The source-drain electrode 135 may serve as a source or a drain of the TFT 10a, and may include, for example, a metal or a transparent electrically-conductive film similar to those described as the material for forming the gate electrode 133. A material with high electric conductivity may be preferably selected as the material of the source-drain electrode 135.

The display device layer 14 may include a plurality of pixels and a display device. The display device may be driven for display by a backplane on which a plurality of TFTs 10a are disposed. Examples of the display device may include an organic EL device. The organic EL device may include, for example, an anode electrode, an organic electro-luminescence layer, and a cathode electrode in order from the TFT layer 13. The anode electrode may be coupled to the source-drain electrode 135 of the TFT 10a. The cathode electrode may be supplied with cathode potential common to the pixels, for example, through wiring lines WL2 described later,

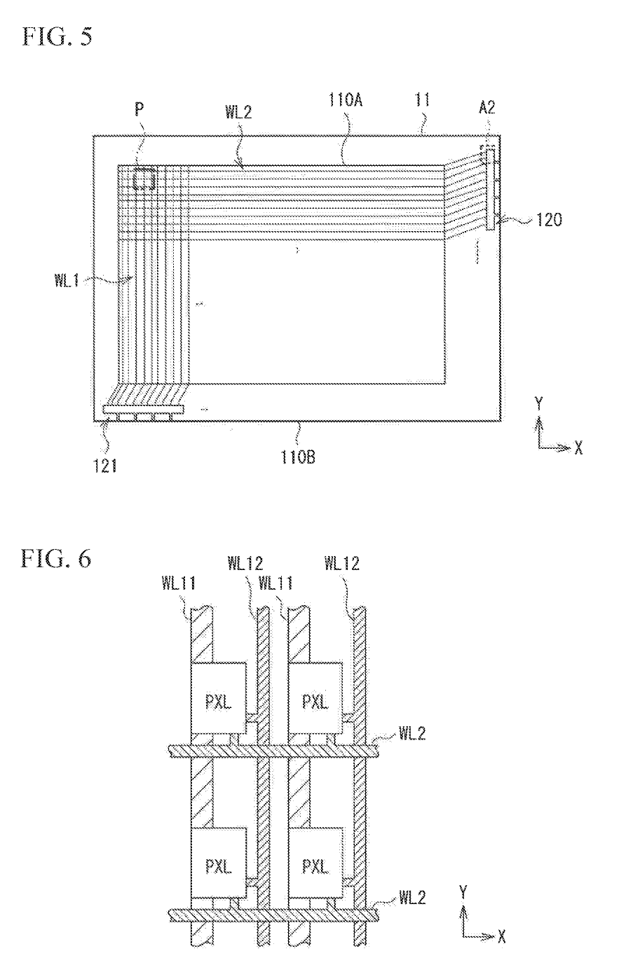

FIG. 5 is an explanatory schematic plan view of a wiring line configuration (a configuration of the backplane) of the display unit 1. FIG. 6 illustrates a portion corresponding to a region P illustrated in FIG. 5 in an enlarged manner.

Wiring lines WL1 may be disposed along a Y direction and the wiring lines WL2 may be disposed along an X direction, in a display region 110A on the substrate 11. Terminal sections 120 and 121 that respectively supply potential to the wiring lines WL2 and WL1 may be disposed in a peripheral region 110B of the display region 110A.

Each of the wiring lines WL1 and WL2 may serve as one of, for example, a signal line, a scanning line, a power supply line, and a common potential line. An intersection between each of the wiring lines WL1 and each of the wiring lines WL2 may correspond to one pixel PXL. The wiring lines WL1 and WL2 may be extended from the display region 110A to the peripheral region 110B, and may be respectively coupled to the terminal sections 121 and 120 in the peripheral region 110B. The wiring lines WL2 may include, for example, common potential lines (cathode lines), and may be coupled to the terminal section 120 in the peripheral region 110B. Each of the wiring lines WL1 may include, for example, wiring lines WL11 and WL12. Note that, in FIG. 6, the configuration of the circuit and the wiring lines in the backplane is schematically illustrated; however, the wiring lines WL11 may serve as power supply lines, the wiring lines WL12 may serve as signal lines, and the wiring lines WL2 may serve as common potential lines (cathode lines), for example.

The terminal sections 120 and 121 may be provided to respectively supply potential to the wiring lines WL2 and WL1, and may be coupled to an unillustrated power supply. Among them, the terminal section 120 may include, for example, a terminal portion that supplies fixed potential such as cathode potential. Note that, in this example, the configuration is exemplified in which the terminal sections 120 and 121 are respectively provided on two sides of the rectangular substrate 11; however, the terminal sections 120 and 121 either may be provided on only one side, or may be provided on three or four sides of the substrate 11.

Note that, although the TFT 10a is not illustrated in FIG. 5 and FIG. 6, in this example, a case is assumed in which one TFT 10a is disposed in one pixel PXL. The number of the TFT 10a, however, is not limited, and two or more TFTs 10a may be disposed in one pixel PXL.

### [Manufacturing Method]

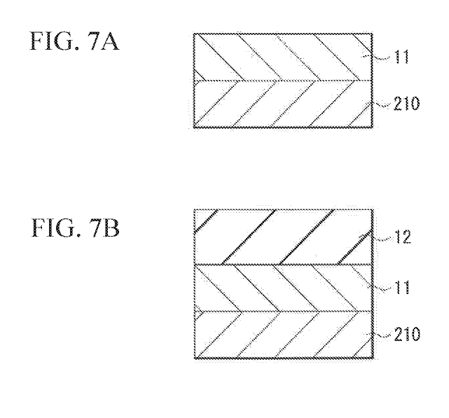

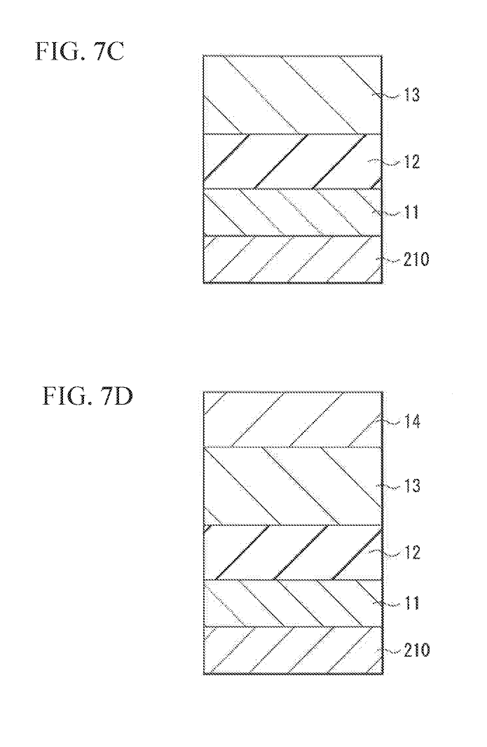

The above-described display unit 1 may be manufactured, for example, in the following manner. FIG. 7A to FIG. 7D illustrate processes of manufacturing the display unit 1 in step order.

First, as illustrated in FIG. 7A, a support substrate 210 may be joined to a rear surface of the substrate 11. The support substrate 210 may be made of, for example, glass, and the substrate 11 may be configured by, for example, a flexible substrate. Thereafter, as illustrated in FIG. 7B, the barrier film 12 may be formed on an entire surface of the substrate 11 supported by the support substrate 210. The barrier film 12 may be formed, for example, in the following manner. First, for example, silica nanoparticles as the inorganic polymer compound and a siloxane organic material as the organic matter may be mixed in a solvent, and the mixture may be applied to the entire surface of the substrate 11 through spin coating. Thereafter, baking treatment may be performed at predetermined temperature, which results in formation of the barrier film 12. The inorganic polymer compound and the organic matter may be applied onto the substrate 11 through, for example, slit coating. Alternatively, the film of the inorganic polymer compound and the organic matter may be formed by a method other than coating. When the barrier film 12 contains the silica nanoparticles and the siloxane organic material, a crosslinked structure of the interparticle region BP may be formed by the above-described baking treatment.

Next, as illustrated in FIG. 7C, the TFT layer 13 may be formed. As an example, the TFT 10a illustrated in FIG. 4 may be formed. More specifically, first, the semiconductor layer 131 made of the above-described material (such as an oxide semiconductor) may be formed on the barrier film 12 through, for example, sputtering. Thereafter, the semiconductor layer 131 may be patterned in a predetermined shape through, for example, photolithography and etching. Subsequently, the gate insulating film 132 made of the above-described material may be formed through, for example, a chemical vapor deposition (CVD) method. Thereafter, the gate electrode 133 made of the above-described material may be formed on the gate insulating film 132 through patterning, and the gate insulating film 132 may be then etched with use of the gate electrode 133 as a mask to pattern the gate insulating film 132. Subsequently, the protection film 134 and the interlayer insulating film 136A may be formed, and the contact hole H1 may be then formed in a region facing a portion of the semiconductor layer 131. Thereafter, the source-drain electrode 135 made of the above-described metal material may be so formed on the interlayer insulating film 136A as to bury the contact hole H1. As a result, the TFT 10a may be formed.

Subsequently, as illustrated in FIG. 7D, the display device layer 14 may be formed on the TFT layer 13. For example, when the display device layer 14 includes an organic EL device, the display device layer 14 that includes, for example, the anode electrode, the organic electro-luminescence layer, and the cathode electrode may be formed on the TFT layer 13.

After the formation of the display device layer 14, the support substrate 210 may be detached. As a result, the display unit 1 illustrated in FIG. 1 may be completed.

### [Workings and Effects]

In the display unit 1 according to the present embodiment, the pixels of the display device layer 14 may be driven for display, on the basis of an image signal inputted from outside, and the image may be displayed. At this time, in the TFT layer 13, for example, the TFT 10a may be driven by a voltage for each pixel. More specifically, when a voltage equal to or higher than a threshold voltage is supplied to the gate electrode 133 of the TFT 10a of a certain pixel, the semiconductor layer 131 may be activated (may form a channel), which causes a current to flow between the paired source-drain electrodes 135.

Here, a case is considered, where the barrier film on the substrate is made of only the inorganic polymer compound, namely, a case where the barrier film contains no organic matter. Such a barrier film made of only the inorganic polymer compound may be, for example, spin-on-glass (SOG), and may be formed by application of the silica material solved in a solvent, onto the substrate.

As described above, when the barrier film contains no organic matter, the viscosity of the raw material of the barrier film before application may become low. Therefore, it is not possible to increase the thickness of the barrier film. It is not possible for a thin barrier film to effectively planarize the substrate, and irregularities of the substrate may deteriorate characteristics and reliability of each of the TFT layer and the display device layer. In addition, crack may occur on the thin barrier film itself due to irregularities of the substrate. Furthermore, in a case where the barrier film contains no organic matter, crack may easily occur in the barrier film even when the thickness of the barrier film is increased. When a crack occurs in the barrier film, the barrier function may be deteriorated, and the characteristics and the reliability of each of the TFT layer and the display device layer may be impaired accordingly. Irregularities caused by the crack in the barrier film may influence the TFT layer and the display device layer.

In contrast, in the present embodiment, the barrier film 12 on the substrate 11 contains the organic matter in addition to the inorganic polymer compound. This increases the viscosity of the raw material of the barrier film 12 before application, as compared with the barrier film containing no organic matter, which makes it possible to easily increase the thickness of the barrier film 12. The thick barrier film 12 effectively planarizes irregularities of the substrate 11, which makes it possible to suppress the influence of the irregularities of the substrate 11 on the TFT layer 13 and the display device layer 14. In addition, crack is difficult to occur in the thick barrier film 12, which makes it possible to stably retain the barrier function of the barrier film 12. Accordingly, it is possible to stably maintain the characteristics and the reliability of the display unit 1.

In particular, when the substrate 11 is a resin substrate, irregularities may easily occur on the substrate 11. Therefore, providing the barrier film 12 containing the organic matter makes it possible to largely improve the characteristics and the reliability of the display unit 1.

In addition, when the barrier film 12 contains the particles 12P such as silica nanoparticles, and the particles 12P are cross-linked by the organic matter, the positions of the respective particles 12P may be fixed. This improves stability of the barrier film 12 and improves durability to the manufacturing process, etc.

As described above, in the present embodiment, the barrier film 12 on the substrate 11 contains the organic matter in addition to the inorganic polymer compound. This increases the viscosity of the raw material when forming the barrier film, as compared with the case where the barrier film is made of only the inorganic polymer compound. This makes it possible to easily increase the thickness of the barrier film 12. The barrier film 12 with a large thickness makes it possible to effectively planarize the substrate 11 and to make a crack less likely to occur. Accordingly, it is possible to stably maintain the characteristics and the reliability of the display unit 1.

Modification examples of the present embodiment are described below. In the following description, the same reference numerals are assigned to the same components as those of the above-described embodiment, and description thereof is omitted where appropriate.

### Modification Example 1

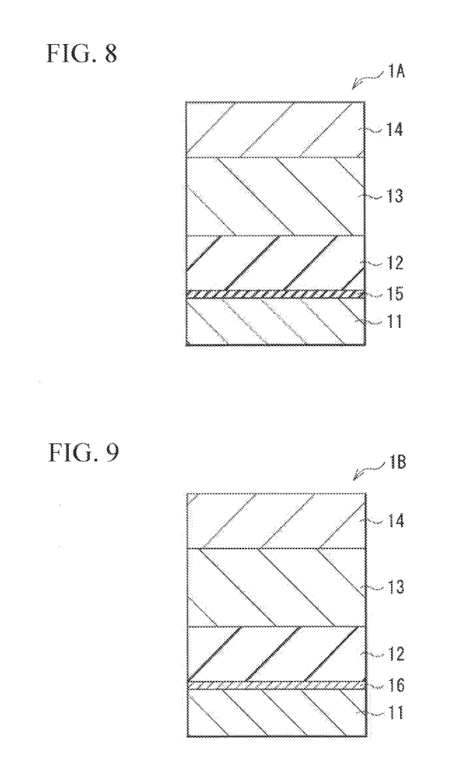

FIG. 8 illustrates a cross-sectional configuration of a display unit (a display unit 1A) according to Modification Example 1 of the above-described embodiment. The display unit 1A may include an insulating film 15 between the substrate 11 and the barrier film 12. Except this point, the display unit 1A has a configuration, workings, and effects similar to those of the display unit 1 of the above-described embodiment. Note that the insulating film 15 corresponds to a specific but non-limiting example of a “first inorganic insulating film” in one embodiment of the technology.

The insulating film 15 may prevent a substance that may become a contamination source, from moving from the substrate 11 to the TFT layer 13 and the display device layer 14. In other words, providing the insulating film 15 in addition to the barrier film 12 may enhance a barrier property. In addition, providing the insulating film 15 on the surface of the substrate 11 causes the barrier film 12 to be easily adhered closely to the substrate 11 (the insulating film 15). This improves reliability of the display unit 1A in mechanical deterioration such as bending and ball drop.

The insulating film 15 may be made of, for example, an inorganic insulating material, and may be provided on the entire surface of the substrate 11. The insulating film 15 may be a monolayer film or a layered film containing one or more of, for example, silicon oxide (SiOₓ), silicon nitride (SiN), and silicon oxynitride (SiON). In addition, aluminum oxide (Al₂O₃) may be used for the insulating film 15. The insulating film 15 may have a thickness of, for example, 50 nm to 5 μm.

Providing the insulating film 15 between the substrate 11 and the barrier film 12 in the display unit 1A makes it possible to more effectively suppress movement of the contamination source from the substrate 11 to the upper layer. In addition, close adhesion of the barrier film 12 is enhanced and the reliability of the display unit 1A is improved.

### Modification Example 2

FIG. 9 illustrates a cross-sectional configuration of a display unit (a display unit 1B) according to Modification Example 2 of the above-described embodiment. The display unit 1B may include an electric field shielding film 16 between the substrate 11 and the barrier film 12. Except this point, the display unit 1B has a configuration, workings, and effects similar to those of the display unit 1 of the above-described embodiment.

For example, the electric field shielding film 16 may be provided on the entire surface of the substrate 11. The electric field shielding film 16 may be configured by an electrically-conductive film, preferably configured by a transparent electrically-conductive film. Examples of the transparent electrically-conductive film may include an oxide semiconductor that contains, as a main component, an oxide of one or more of elements such as indium, gallium, zinc, tin, titanium, and niobium. Among them, as the transparent electrically-conductive film, for example, a material or a degenerate semiconductor that hardly absorbs light of a wavelength in a range from 600 nm to 1100 nm, may be preferably used. As an example, ITO, IZO, amorphous silicon (n⁺a-Si) in which n-type impurity is diffused with high density may be used. The electric field shielding film 16 may be a monolayer film containing the above-described material, or a layered film containing the above-described material. Using such a transparent electrically-conductive film makes it possible to suppress occurrence of damage caused by a laser beam when a defective part is repaired (when laser repair is performed) in a metal wiring line formed in the upper layer, for example, the TFT layer 13 and the display device layer 14. The electric field shielding film 16, however, is not limited to the above-described transparent electrically-conductive film, and metal such as molybdenum (Mo), tungsten (W), and aluminum (Al) may be used for the electric field shielding film 16.

The thickness of the electric field shielding film 16 may be, for example, in a range from 10 nm to 300 nm, and more specifically, 20 nm. The sheet resistance of the electric field shielding film 16 may be, for example, in a range from 1 n/cm² to 1 MΩ/cm².

The electric field shielding film 16 may be maintained at fixed potential. In other words, the electric field shielding film 16 may be supplied with fixed potential. More specifically, the electric field shielding film 16 may be maintained at ground (GND) potential (for example, 0 V). In this case, the electric field shielding film 16 may be electrically coupled to the terminal section that is provided to supply the fixed potential, in the peripheral region 110B (an end of the substrate 11, see FIG. 5).

Such an electric field shielding film 16 may be provided to suppress variation of the threshold voltage of the TFT 10a caused by bias stress, as described below.

When a voltage equal to or higher than the threshold voltage is applied to the gate electrode of the TFT and a current accordingly flows between the source-drain electrodes, an electric field may be generated between the substrate and the semiconductor layer. When the electric field reaches the substrate, occurrence of a causing substance may be induced inside the substrate. Alternatively, an electric charge may occur on the surface of the substrate. Such a causing substance and an electric charge may influence the semiconductor layer, which may cause variation in the threshold voltage of the TFT due to the bias stress.

In this example, the electric field shielding film 16 is provided between the substrate 11 and the TFT 10a (the TFT layer 13), and thus the above-described electric field is shielded. In other words, it is possible to prevent occurrence of the causing substance inside the substrate 11 and occurrence of the electric charge on the surface of the substrate 11 that are caused by the electric field. This makes it possible to suppress variation in the threshold voltage of the TFT 10a caused by the bias stress.

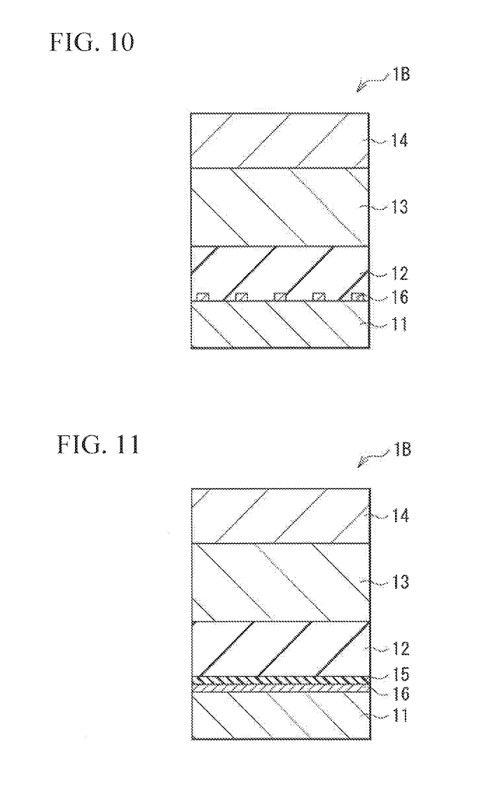

As illustrated in FIG. 10, the electric field shielding film 16 may be provided in a selective region on the surface of the substrate 11. Providing the electric field shielding film 16 in the selective region reduces a parasitic capacitance, which makes it possible to suppress generation of a leakage current.

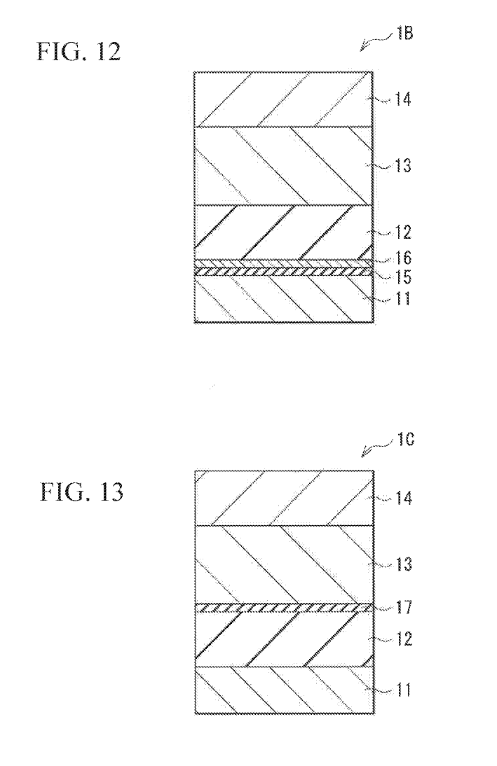

As illustrated in FIG. 11 and FIG. 12, the insulating film 15 may be provided together with the electric field shielding film 16. For example, such a display unit 1B may include the substrate 11, the electric field shielding film 16, the insulating film 15, the barrier film 12, the TFT layer 13, and the display device layer 14 that are stacked in this order (FIG. 11). The display unit 1B may also have a configuration in which the substrate 11, the insulating film 15, the electric field shielding film 16, the barrier film 12, the TFT layer 13, and the display device layer 14 are stacked in this order (FIG. 12). In terms of a parasitic capacitance, it is preferable to adopt the order of stacking the electric field shielding film 16 and the insulating film 15 as illustrated in FIG. 11.

### Modification Example 3

FIG. 13 illustrates a cross-sectional configuration of a display unit (a display unit 1C) according to Modification Example 3 of the above-described embodiment. The display unit 1C may include an insulating film 17 between the barrier film 12 and the TFT layer 13. Except this point, the display unit 1C has a configuration, workings, and effects similar to those of the display unit 1 according to the above-described embodiment. Note that the insulating film 17 corresponds to a specific but non-limiting example of a “second inorganic insulating film” in one embodiment of the technology.

The insulating film 17 may be provided to prevent a substance that may become a contamination source, from moving from the substrate 11 to the TFT layer 13 and the display device layer 14. In other words, providing the insulating film 17 in addition to the barrier film 12 may enhance a barrier property.

The insulating film 17 may be made of, for example, an inorganic insulating material, and may be provided on an entire surface of the barrier film 12 (the substrate 11). The insulating film 17 may be made of a material similar to that of the above-described insulating film 15. The insulating film 17 may have a thickness of, for example, 50 nm to 5 μm.

Providing the insulating film 17 between the barrier film 12 and the TFT layer 13 in the display unit 1C makes it possible to more effectively suppress movement of the contamination source from the substrate 11 to the upper layer.

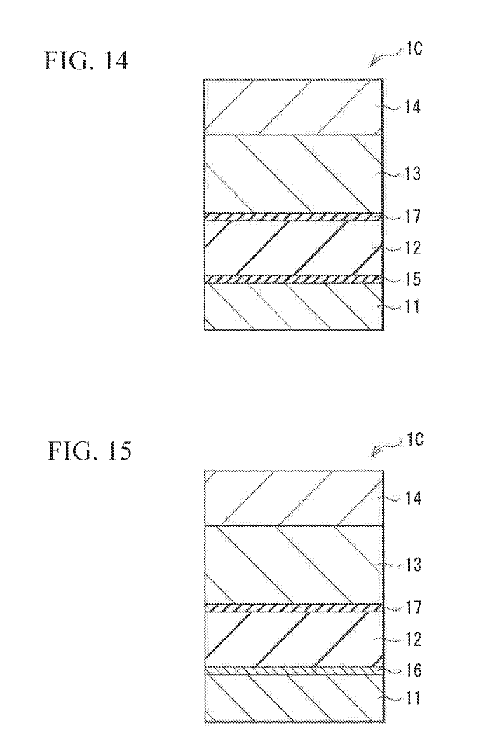

As illustrated in FIG. 14, the insulating film 15 may also be provided between the substrate 11 and the barrier film 12, in addition to the insulating film 17.

As illustrated in FIG. 15, the electric field shielding film 16 may also be provided between the substrate 11 and the barrier film 12, in addition to the insulating film 17.

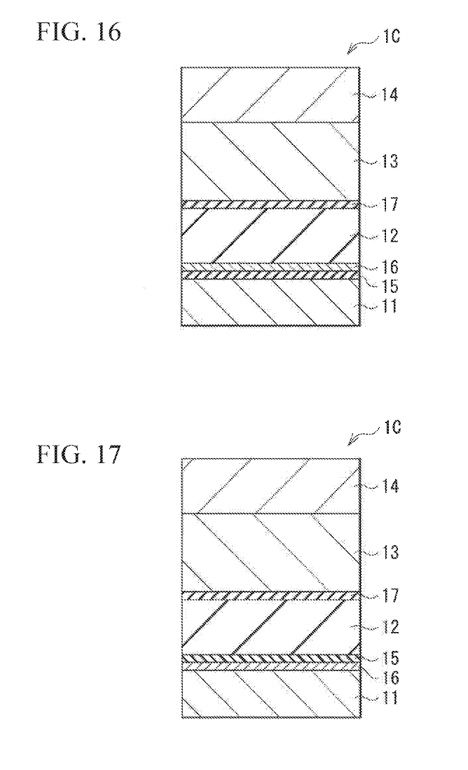

As illustrated in FIG. 16 and FIG. 17, the insulating film 15 and the electric field shielding film 16 may also be provided between the substrate 11 and the barrier film 12, in addition to the insulating film 17. More specifically, the substrate 11, the insulating film 15, the electric field shielding film 16, the barrier film 12, the insulating film 17, the TFT layer 13, and the display device layer 14 may be stacked in this order (FIG. 16). Alternatively, the substrate 11, the electric field shielding film 16, the insulating film 15, the barrier film 12, the insulating film 17, the TFT layer 13, and the display device layer 14 may be stacked in this order (FIG. 17).

### Modification Example 4

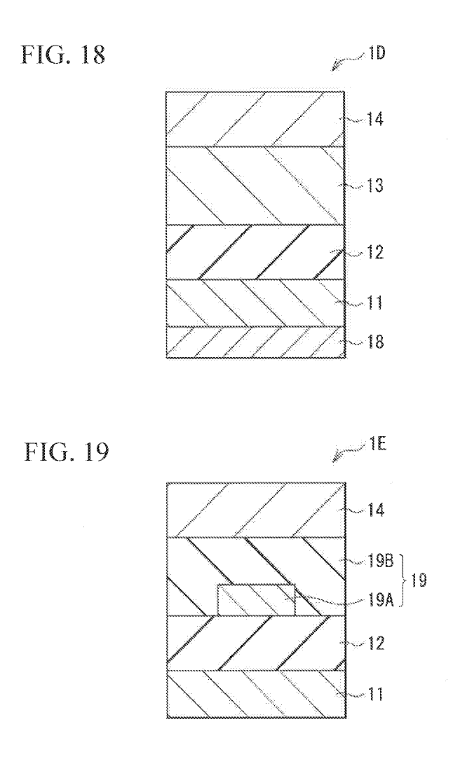

FIG. 18 illustrates a cross-sectional configuration of a display unit (a display unit 1D) according to Modification Example 4 of the above-described embodiment. The display unit 1D may include a metal thin film 18 on the rear surface of the substrate 11. Except this point, the display unit 1D has a configuration, workings, and effects similar to those of the display unit 1 of the above-described embodiment.

The metal thin film 18 may be provided to protect and reinforce the substrate 11, for example, in a case where the substrate 11 is configured by a flexible substrate (a substrate made of an organic material), or other cases. The metal thin film 18 may be joined to a surface of the substrate 11, opposite to the surface provided with the barrier film 12. In other words, the metal thin film 18 may be joined to the rear surface of the substrate 11.

### Modification Example 5

FIG. 19 illustrates a cross-sectional configuration of a display unit (a display unit 1E) according to Modification Example 5 of the above-described embodiment. The display unit 1E may include a wiring line layer 19 in place of the TFT layer (the TFT layer 13 of FIG. 1). Except this point, the display unit 1E has a configuration, workings, and effects similar to those of the display unit 1 of the above-described embodiment.

For example, the wiring line layer 19 may include an electrically-conductive layer 19A and an interlayer insulating film 19B. The electrically-conductive layer 19A may be provided in, for example, a selective region on the barrier film 12, and the interlayer insulating film 19B may be so provided on the entire surface of the barrier film 12 as to cover the electrically-conductive layer 19A. In this example, the substrate 11, the barrier film 12, and the wiring line layer 19 (the electrically-conductive layer 19A) correspond to a specific but non-limiting example of an “electronic device” in one embodiment of the technology.

### <Functional Configuration Example of Display Unit>

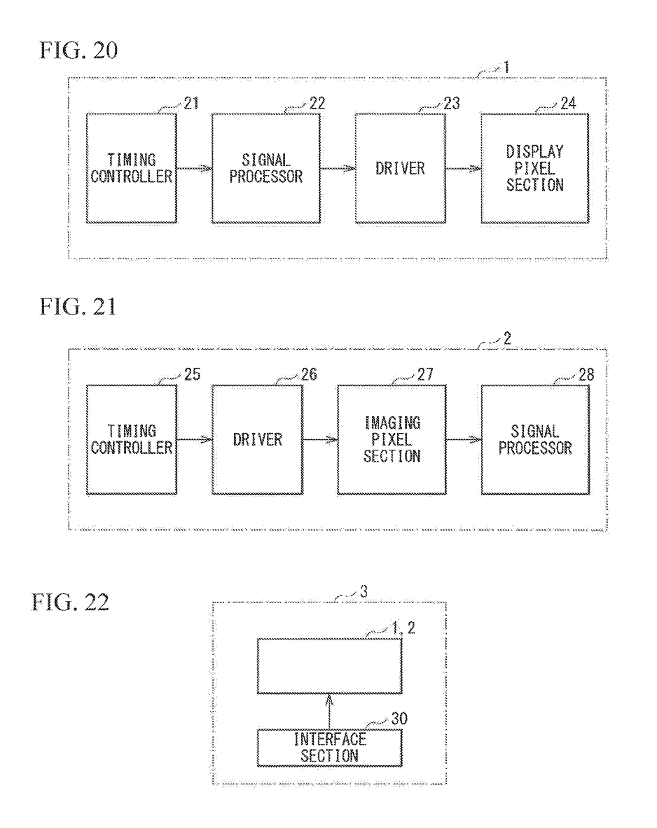

FIG. 20 illustrates a functional block configuration of any of the display units 1, 1A, 1B, 1C, 1D, and 1E (hereinafter, referred to representatively as the display unit 1) described in the foregoing respective embodiments, modification examples, and application examples.

The display unit 1 may display, as an image, an image signal inputted from outside or an image signal generated inside, and may also be applied to, for example, a liquid crystal display, in addition to the above-described organic EL display. The display unit 1 may include, for example, a timing controller 21, a signal processor 22, a driver 23, and a display pixel section 24.

The timing controller 21 may include a timing generator that generates various timing signals (control signals), and may perform drive control of the signal processor 22 and other sections on the basis of the various timing signals. The signal processor 22 may perform, for example, predetermined correction on a digital image signal inputted from outside, and may output the thus-obtained image signal to the driver 23. The driver 23 may include, for example, a scanning line drive circuit and a signal line drive circuit, and may drive pixels of the display pixel section 24 through the various control lines. The display pixel section 24 may include, for example, a display device (the above-described display device layer 14) such as an organic EL device and a liquid crystal display device, and a pixel circuit that drives the display device for each pixel. Among them, the above-described TFT 10a may be used, for example, in various circuits that configure a portion of the driver 23 or the display pixel section 24.

### <Example of Imaging Unit>

In the above-described embodiments, modification examples, and application examples, the display unit 1 has been described as one of the application examples of the electronic device including the barrier film 12. The electronic device, however, may also be used in an imaging unit (an imaging unit 2) illustrated in FIG. 21, in addition to the display unit 1.

The imaging unit 2 may be a solid-state imaging unit that obtains an image as an electric signal, for example. The imaging unit 2 may include a charge-coupled device (CCD) image sensor, a complementary metal oxide semiconductor (CMOS) image sensor, or any other suitable image sensor. The imaging unit 2 may include, for example, a timing controller 25, a driver 26, an imaging pixel section 27, and a signal processor 28.

The timing controller 25 may include a timing generator that generates various timing signals (control signals). The timing controller 25 may control driving of the driver 26, on the basis of the various timing signals. The driver 26 may include circuits including a row selection circuit, an AD conversion circuit, and a horizontal transfer scanning circuit. The driver 26 may perform driving that reads out signals from respective pixels provided in the imaging pixel section 27 through various control lines. The imaging pixel section 27 may include an imaging device (a photoelectric conversion device), and a pixel circuit designed to read out the signals. The signal processor 28 may apply various signal processes to the signals obtained from the imaging pixel section 27. The above-described TFT 10a may be used in, for example, various circuits configuring a portion of the driver 26 or the imaging pixel section 27.

### <Example of Electronic Apparatus>

The display unit 1 (or the imaging unit 2) described in the foregoing embodiments, modification examples, and application examples may be used in various electronic apparatuses. FIG. 22 illustrates a functional block configuration of an electronic apparatus 3. Examples of the electronic apparatus 3 may include a television, a personal computer (PC), a smartphone, a tablet PC, a mobile phone, a digital still camera, and a digital video camera.

The electronic apparatus 3 may include, for example, the above-described display unit 1 (or the imaging unit 2) and an interface section 30. The interface section 30 may be an input section that receives, for example, various signals and power from outside. The interface section 30 may further include a user interface such as a touch panel, a keyboard, and an operation button.

Hereinbefore, the foregoing embodiments, modification examples, and application examples have been described; however, the technology is not limited to the foregoing embodiments, modification examples, and application examples, and may be modified in a wide variety of ways. For example, factors such as a material and a thickness of each layer exemplified in the foregoing embodiments, modification examples, and application examples are illustrative and non-limiting. Any other material, any other thickness, and any other factor may be adopted besides those described above.

Moreover, the effects described in the foregoing embodiments, modification examples, and application examples are mere examples. The effects according to an embodiment of the disclosure may be effects other than those described hereinabove. The disclosure may further include other effects in addition to those described above.

Note that the technology may also have the following configurations.

(1)

An electronic device including:

a substrate;

a barrier film provided on the substrate, the barrier film containing an inorganic polymer compound and an organic matter; and one of an electrically-conductive layer and a semiconductor layer that are each provided on the substrate with the barrier film in between.

(2)

The electronic device according to (1), wherein the inorganic polymer compound includes a silica compound.

(3)

The electronic device according to (2), wherein the inorganic polymer compound contains silica nanoparticles.

(4)

The electronic device according to (3), wherein the silica nanoparticles are crosslinked by the organic matter.

(5)

The electronic device according to any one of (1) to (4), wherein the organic matter includes a siloxane organic compound.

(6)

The electronic device according to any one of (1) to (5), wherein the barrier film is provided on an entire surface of the substrate.

(7)

The electronic device according to any one of (1) to (6), further including a first inorganic insulating film between the substrate and the barrier film.

(8)

The electronic device according to any one of (1) to (6), further including an electric field shielding film between the substrate and the barrier film.

(9)

The electronic device according to (8), wherein the electric field shielding film is provided on an entire surface of the substrate.

(10)

The electronic device according to (8), wherein the electric field shielding film is provided in a selective region on the substrate.

(11)

The electronic device according to any one of (1) to (5), further including a first inorganic insulating film and an electric field shielding film between the substrate and the barrier film.

(12)

The electronic device according to any one of (1) to (11), further including a second inorganic insulating film between the barrier film and the electrically-conductive layer or between the barrier film and the semiconductor layer.

(13)

The electronic device according to any one of (1) to (12), further including a transistor that includes the semiconductor layer.

(14)

The electronic device according to (13), wherein the transistor includes a gate electrode and a source-drain electrode, the gate electrode facing the semiconductor layer, and the source-drain electrode being electrically coupled to the semiconductor layer.

(15)

The electronic device according to any one of (1) to (14), wherein the substrate includes a flexible substrate.

(16)

A display unit, including:

a substrate;

a barrier film provided on the substrate, the barrier film containing an inorganic polymer compound and an organic matter;

one of an electrically-conductive layer and a semiconductor layer that are each provided on the substrate with the barrier film in between; and

a display device layer provided on one of the electrically-conductive layer and the semiconductor layer, the display device layer including a plurality of pixels.

(17)

An electronic apparatus provided with a display unit, the display unit including:

a substrate;

a barrier film provided on the substrate, the barrier film containing an inorganic polymer compound and an organic matter;

one of an electrically-conductive layer and a semiconductor layer that are each provided on the substrate with the barrier film in between; and

a display device layer provided on one of the electrically-conductive layer and the semiconductor layer, the display device layer including a plurality of pixels.

In the electronic device, the display unit, and the electronic apparatus according to the respective embodiments of the technology, the barrier film contains the organic matter in addition to the inorganic polymer compound. This easily increases the viscosity of the raw material when forming the barrier film.

The electronic device, the display unit, and the electronic apparatus according to the respective embodiments of the technology make it possible to easily increase the thickness of the barrier film because the barrier film contains the organic matter in addition to the inorganic polymer compound. This makes it possible to stably maintain its characteristics.

It should be understood by those skilled in the art that various modifications, combinations, sub-combinations, and alterations may occur depending on design requirements and other factors insofar as they are within the scope of the appended claims or the equivalents thereof.

What is claimed is:

1. An electronic device comprising:
a substrate;
a barrier film provided on the substrate, the barrier film containing an inorganic polymer compound and an organic matter; and
one of an electrically-conductive layer and a semiconductor layer that are each provided on the substrate with the barrier film in between.

2. The electronic device according to claim 1, wherein the inorganic polymer compound comprises a silica compound.

3. The electronic device according to claim 2, wherein the inorganic polymer compound contains silica nanoparticles.

4. The electronic device according to claim 3, wherein the silica nanoparticles are crosslinked by the organic matter.

5. The electronic device according to claim 1, wherein the organic matter comprises a siloxane organic compound.

6. The electronic device according to claim 1, wherein the barrier film is provided on an entire surface of the substrate.

7. The electronic device according to claim 1, further comprising a first inorganic insulating film between the substrate and the barrier film.

8. The electronic device according to claim 1, further comprising an electric field shielding film between the substrate and the barrier film.

9. The electronic device according to claim 8, wherein the electric field shielding film is provided on an entire surface of the substrate.

10. The electronic device according to claim 8, wherein the electric field shielding film is provided in a selective region on the substrate.

11. The electronic device according to claim 1, further comprising a first inorganic insulating film and an electric field shielding film between the substrate and the barrier film.

12. The electronic device according to claim 1, further comprising a second inorganic insulating film between the barrier film and the electrically-conductive layer or between the barrier film and the semiconductor layer.

13. The electronic device according to claim 1, further comprising a transistor that includes the semiconductor layer.

14. The electronic device according to claim 13, wherein the transistor includes a gate electrode and a source-drain electrode, the gate electrode facing the semiconductor layer, and the source-drain electrode being electrically coupled to the semiconductor layer.

15. The electronic device according to claim 1, wherein the substrate comprises a flexible substrate.

16. A display unit, comprising:
a substrate;
a barrier film provided on the substrate, the barrier film containing an inorganic polymer compound and an organic matter;
one of an electrically-conductive layer and a semiconductor layer that are each provided on the substrate with the barrier film in between; and
a display device layer provided on one of the electrically-conductive layer and the semiconductor layer, the display device layer including a plurality of pixels.

17. An electronic apparatus provided with a display unit, the display unit comprising:
a substrate;
a barrier film provided on the substrate, the barrier film containing an inorganic polymer compound and an organic matter;
one of an electrically-conductive layer and a semiconductor layer that are each provided on the substrate with the barrier film in between; and
a display device layer provided on one of the electrically-conductive layer and the semiconductor layer, the display device layer including a plurality of pixels.
